(19) United States
(12) Patent Application Publication
(10) Pub. No.: US 2024/0145402 A1
(43) Pub. Date: May 2, 2024

(54) SEMICONDUCTOR DIE SHIELDING STRUCTURE

(71) Applicant: Cypress Semiconductor Corporation, San Jose, CA (US)

(72) Inventors: Mark PAVIER, Felbridge (GB); Paul WESTMARLAND, Surrey (GB); Hugh RICHARD, Gravesend (GB)

(21) Appl. No.: 17/973,939

(22) Filed: Oct. 26, 2022

(51) Int. Cl. H01L 23/552; H01L 21/56; H01L 23/00; H01L 25/16

(52) U.S. Cl. CPC H01L 23/552; H01L 21/565; H01L 24/32; H01L 24/48; H01L 24/73; H01L 25/165; H01L 23/66; H01L 2924/182; H01L 2924/3025

(57) ABSTRACT

One or more structures and/or methods are provided. In an example of the subject matter presented herein, an apparatus includes a circuit board, a first component mounted to the circuit board, a shielding structure mounted to the circuit board and having a first platform elevated over the circuit board, and a semiconductor die mounted to the first platform, wherein the shielding structure is between the first component and the semiconductor die.

### BACKGROUND

In device packages, the package footprint is determined by the components mounted to a printed circuit board and any shielding provided for the components. For example, components in the device, such as oscillators, transistors, or other components, may generate electromagnetic interference that may affect the operation of other components, such as a semiconductor die. To reduce the effect of the electromagnetic interference, a shielding structure may be provided between the electromagnetic interference generating components and the components sensitive to the electromagnetic interference.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

In an embodiment of the techniques presented herein, an apparatus is provided. The apparatus comprises a circuit board, a first component mounted to the circuit board, a shielding structure mounted to the circuit board and having a first platform elevated over the circuit board, and a semiconductor die mounted to the first platform, wherein the shielding structure is between the first component and the semiconductor die.

In an embodiment of the techniques presented herein, a shielding structure is provided. The shielding structure comprises a first platform, a first leg connected to the first platform to support the first platform, a second leg spaced apart from the first leg and connected to the first platform to support the first platform, and a first finger extending from the first leg, wherein a first window is defined in the first platform and the first finger extends into the first window.

In an embodiment of the techniques presented herein, a method is provided. The method comprises mounting a first component to a circuit board, mounting a shielding structure having a first platform to the circuit board, and mounting a semiconductor die to the first platform, wherein the shielding structure is between the first component and the semiconductor die.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIGS. 1 and 2 are isometric diagrams of a device, in accordance with some embodiments.

FIGS. 3A-3C are cross-section view of the device during various stages of manufacturing, in accordance with some embodiments.

FIGS. 4A-4C are cross-section view of the device during various stages of manufacturing, in accordance with some embodiments.

FIGS. 5A and 5B are isometric diagrams of the shielding structure during various stages of manufacturing, in accordance with some embodiments.

FIG. 6 is a flow diagram illustrating an example method for fabricating a device, in accordance with some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

All numerical values within the detailed description and the claims herein are modified by “about” or “approximately” the indicated value, and take into account experimental error and variations that would be expected by a person having ordinary skill in the art.

In device packages, the package footprint is determined by the components mounted to a printed circuit board and any shielding structures provided for the components. Such shielding structures can increase the footprint of the device package. According to some embodiments, a shielding structure is provided to provide a mounting surface for semiconductor die. The shielding structure elevates the semiconductor die over other components and provides electromagnetic shielding for the semiconductor die from underlying or adjacent components. In some embodiments, the shielding structure comprises fingers that extend vertically above the support surface. The fingers may provide electromagnetic shielding between the semiconductor die and laterally adjacent devices. In some embodiments, a finger may extend to an upper surface of the device package to contact a shielding cover formed on an upper surface of the device package. Windows may be defined in the mounting surface of the shielding structure to allow wire bonding between the semiconductor die and components or pads on the printed circuit board. In some embodiments, the shielding structure is electrically coupled to a ground plane of the printed circuit board to improve the efficacy of the electromagnetic shielding.

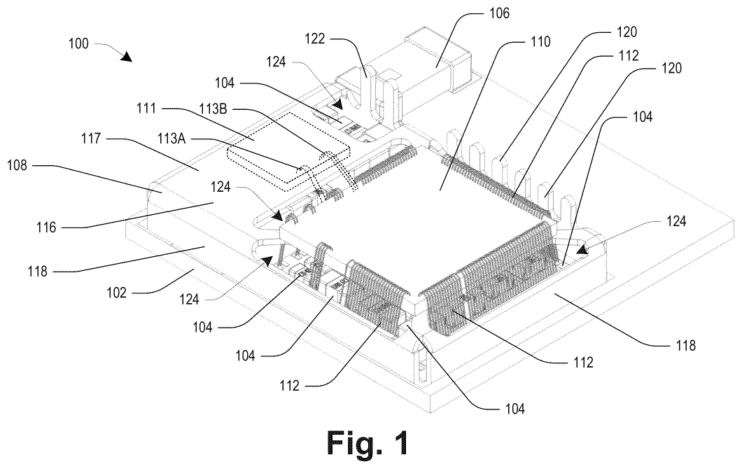

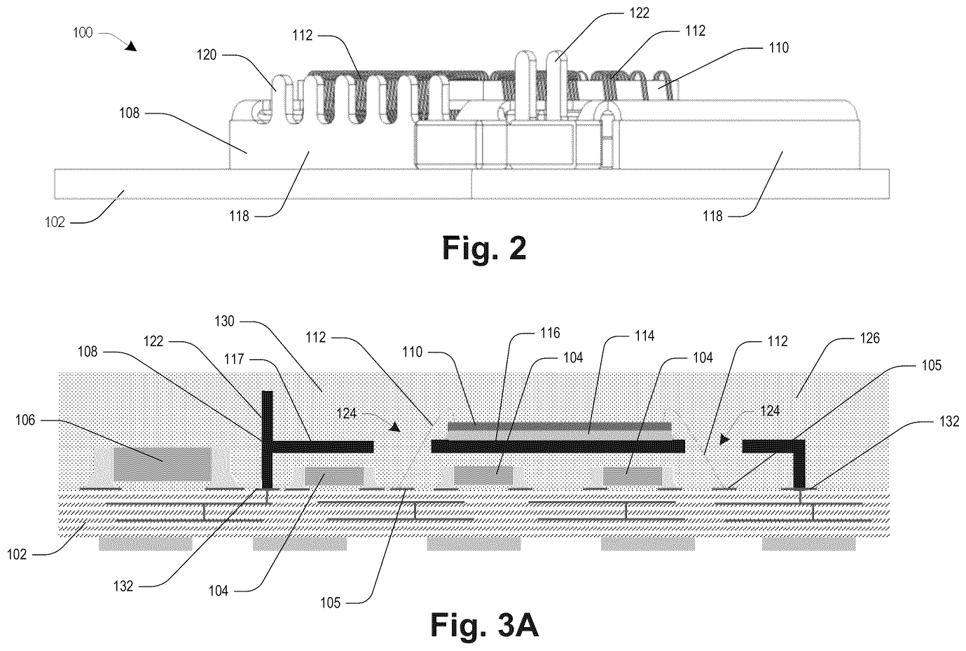

FIGS. 1 and 2 are isometric diagrams of a device 100, in accordance with some embodiments. In some embodiments, the device 100 comprises a circuit board 102, discrete components 104 mounted to the circuit board 102, an antenna 106 mounted to the circuit board 102, a shielding structure 108 mounted to the circuit board 102, a semiconductor die 110 supported by the shielding structure 108, and wire bonds 112 connecting the semiconductor die 110 to the discrete components 104 or to bonding pads on the circuit board 102.

In some embodiments, the shielding structure 108 comprises one or more platforms 116, 117 supported by legs 118 and fingers 120, 122 extending above the platform 116. The platform 116 defines windows 124 that allow the wire bonds 112 to be connected between the semiconductor die 110 and the circuit board 102. The shielding structure 108 may comprise copper, such as a half hard rolled copper material, or a copper alloy.

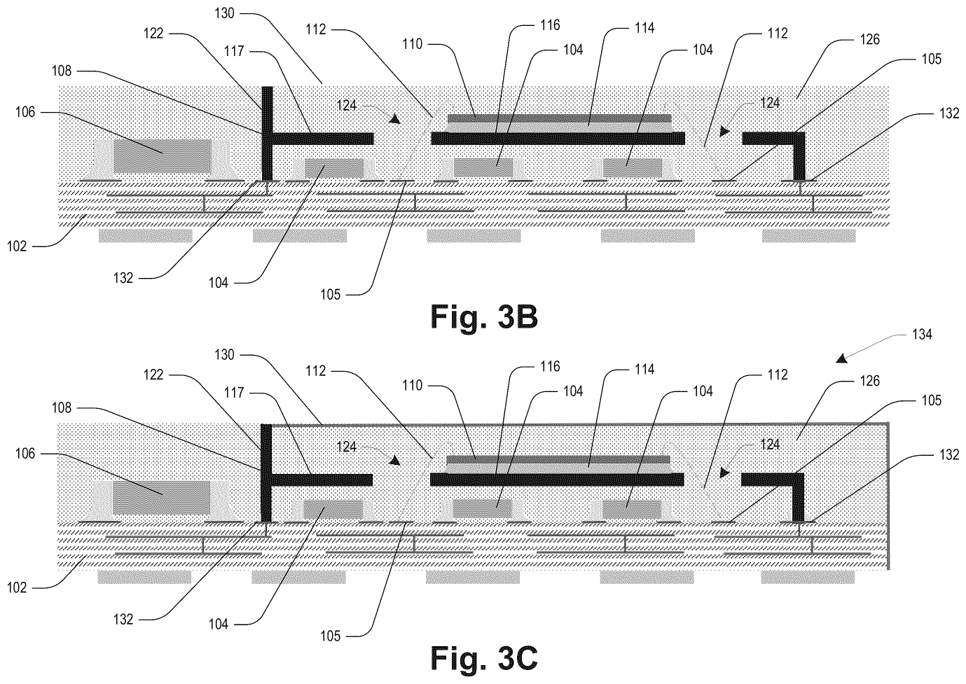

FIGS. 3A-3C are cross-section view of the device 100 during various stages of manufacturing, in accordance with some embodiments. The device 100 is assembled by mounting the discrete components 104 to the circuit board 102, mounting the shielding structure 108 to the circuit board 102, and mounting the semiconductor die 110 to the shielding structure 108 using an adhesive layer 114. The wire bonds 112 are formed, such as by a wire bonding tool, to connect the semiconductor die 110 to a bond pad 105 on the circuit board 102 or to one or more of the discrete components 104.

Referring to FIG. 3A, a mold compound 126 is formed to encapsulate the circuit board 102, the discrete components 104, the antenna 106, the shielding structure 108, and the semiconductor die 110, in accordance with some embodiments. The fingers 120, 122 and windows 124 may facilitate flowing of the mold compound 126 to improve the efficacy of the encapsulation. The mold compound 126 may be an epoxy thermoset compound.

Referring to FIG. 3B, a portion of the mold compound 126 is removed to expose the fingers 122, in accordance with some embodiments. The material removal process may be a grinding process. In some embodiments, the fingers 122 are longer than the fingers 120 such that the material removal process exposes the fingers 122 without exposing the fingers 120.

Referring to FIG. 3C, a shielding cover 130 is formed over the semiconductor die 110, in accordance with some embodiments. The shielding cover 130 may be formed by forming a mask over a portion of the mold compound 126 positioned over the antenna 106 and forming the shielding cover 130 over the unmasked portion of the mold compound 126. In some embodiments, the shielding cover 130 is formed using a sputtering process to deposit a metal material on the unmasked portion of the mold compound 126. The shielding cover 130 contacts the fingers 122, and the shielding structure 108 and the shielding cover 130 form a shielding structure 134 around the semiconductor die 110 to reduce electromagnetic interference.

According to some embodiments, the shielding structure 134 provides shielding to reduce electromagnetic interference generated by the discrete components 104 or interference from the antenna 106. In some embodiments, the shielding structure 108 contacts a ground plane contact 132 of the circuit board 102 to improve the efficacy of the electromagnetic shielding for the semiconductor die 110.

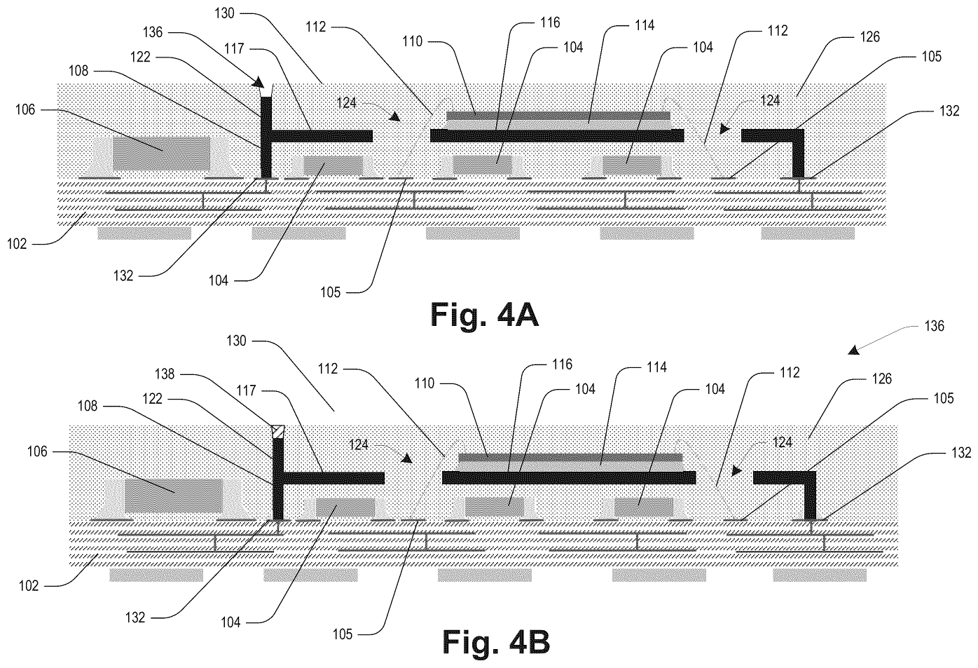

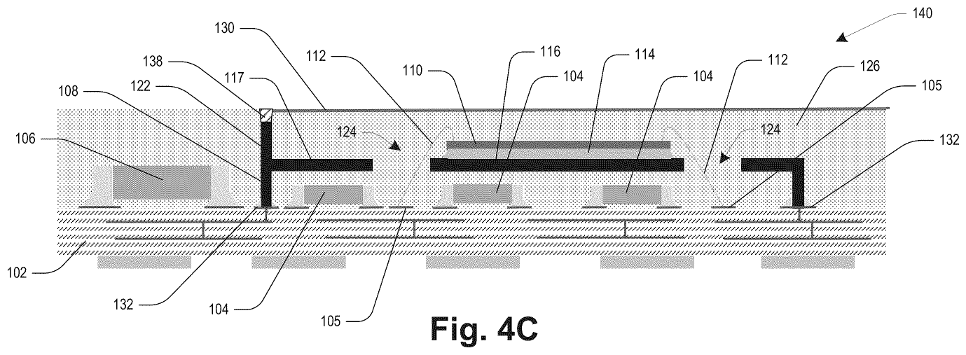

FIGS. 4A-4C are cross-section view of the device 100 during various stages of manufacturing, in accordance with some embodiments. Referring to FIG. 4A, after formation of the mold compound 126, a trench 136 is formed in the mold compound 126 to expose the fingers 122, in accordance with some embodiments. The fingers 122 may not be substantially longer than the fingers 120. The trench 136 may be formed using a laser cut process.

Referring to FIG. 4B, a conductive structure 138 is formed in the trench 136 to contact the fingers 122, in accordance with some embodiments. The conductive structure 138 may be comprise a silver paste.

Referring to FIG. 4C, the shielding cover 130 is formed over an unmasked portion of the mold compound 126 as described above. The shielding cover 130 contacts the conductive structure 138. The shielding structure 108, the conductive structure 138, and the shielding cover 130 form a shielding structure 140 around the semiconductor die 110 to reduce electromagnetic interference.

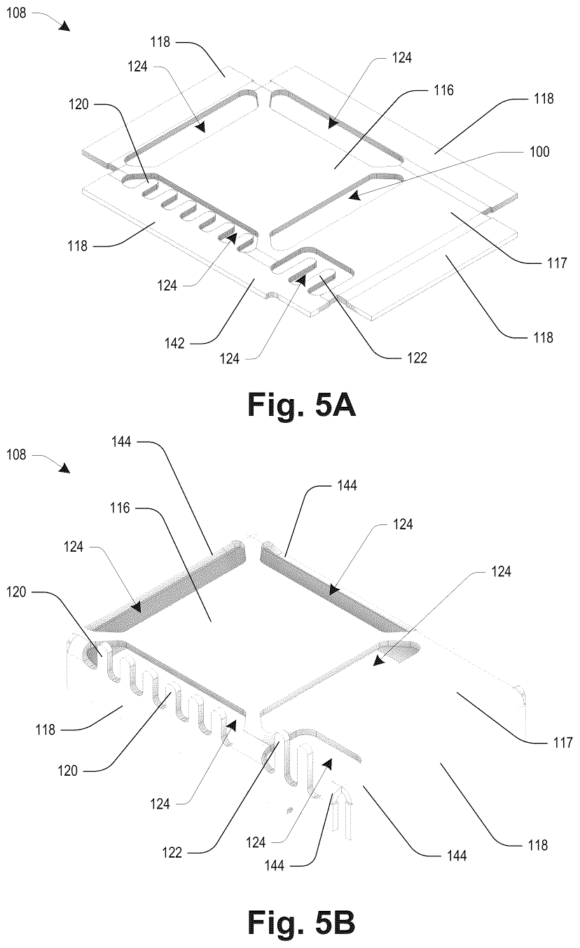

FIGS. 5A and 5B are isometric diagrams of the shielding structure 108 during various stages of manufacturing, in accordance with some embodiments. Referring to FIG. 5A, the shielding structure 108 is formed by stamping, chemical etching, or cutting a flat plate 142 of conductive material to define the features of the shielding structure 108, such as the platforms 116, 117 the legs 118, the fingers 120, 122, and the windows 124. In some embodiments, the fingers 120, 122 extend from the legs 118 into the windows 124. Not all of the windows 124 may have fingers 120 extending from the legs 118. In some embodiments, additional fingers 120 are formed extending from the legs 118 into the windows 124 illustrated in FIG. 5A as not having fingers.

Referring to FIG. 5B, a bending process is performed on the flat plate 142 to define corner portions 144 that position the legs 118 and fingers 120, 122 perpendicular to the platforms 116, 117. The legs 118 extend downward from the platforms 116, 117 and the fingers 120, 122 extend from the legs 118 upward from the platforms 116, 117.

Referring to FIG. 1, the semiconductor die 110 is positioned on the platform 116. In some embodiments, an additional semiconductor die 111 (shown in phantom) may be positioned on the platform 117. The additional die may be connected to the circuit board 102 or discrete components 104 by wire bonds 113A extending through the window 124. The additional semiconductor die 111 may be connected to or to the semiconductor die 110 by wire bonds 113B.

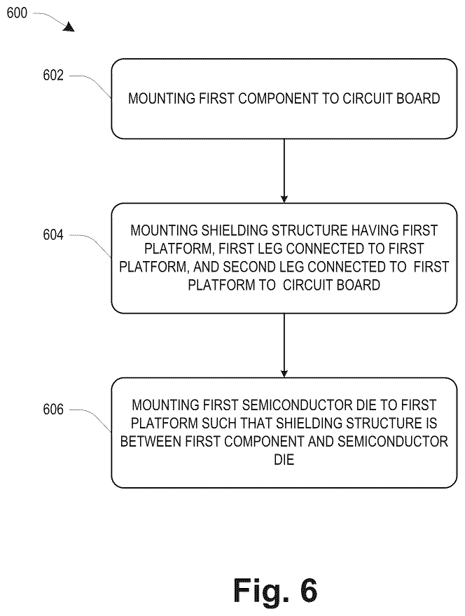

FIG. 6 is a flow diagram illustrating an example method 600 for fabricating a device 100, in accordance with some embodiments. At 602 a first component 104 is mounted to a circuit board 102. At 604, a shielding structure 108 having a first platform 116, a first leg 118 connected to the first platform 116, and a second leg 118 connected to the first platform 116 is mounted to the circuit board 102. At 606, a semiconductor die 110 is mounted to the first platform 116 such that the shielding structure 108 is between the first component 104 and the semiconductor die 110.

In an embodiment of the techniques presented herein, an apparatus is provided. The apparatus includes a circuit board, a first component mounted to the circuit board, a shielding structure mounted to the circuit board and having a first platform elevated over the circuit board, and a semiconductor die mounted to the first platform, wherein the shielding structure is between the first component and the semiconductor die.

In an embodiment of the techniques presented herein, the shielding structure includes a first leg connected to the first platform, and a second leg connected to the first platform.

In an embodiment of the techniques presented herein, the apparatus includes a first window in the first platform, and a wire bond connected to the circuit board and the semiconductor die, wherein the wire bond passes through the first window.

In an embodiment of the techniques presented herein, the apparatus includes a mold compound over the circuit board, the shielding structure, and the semiconductor die.

In an embodiment of the techniques presented herein, the shielding structure includes a first leg connected to the first platform, and a first finger extending from the first leg, and the apparatus includes a shield cover over the mold compound and connected to the first finger.

In an embodiment of the techniques presented herein, the shielding structure includes a second finger extending from the first leg, and the first finger has a length greater than a length of the second finger.

In an embodiment of the techniques presented herein, the shielding structure includes a first leg connected to the first platform, and a first finger extending from the first leg, and the apparatus includes a shield cover over the mold compound, and a conductive structure in the mold compound connecting the first finger and the shield cover.

In an embodiment of the techniques presented herein, the shielding structure is coupled to a ground plane contact of the circuit board.

In an embodiment of the techniques presented herein, the shielding structure includes a second platform, and the apparatus includes another semiconductor die mounted to the second platform.

In an embodiment of the techniques presented herein, a shielding structure is provided. The shielding structure includes a first platform, a first leg connected to the first platform to support the first platform, a second leg spaced apart from the first leg and connected to the first platform to support the first platform, and a first finger extending from the first leg, wherein a first window is defined in the first platform and the first finger extends into the first window.

In an embodiment of the techniques presented herein, the shielding structure includes a second finger extending from the first leg and into the first window.

In an embodiment of the techniques presented herein, the first finger has a length greater than a length of the second finger.

In an embodiment of the techniques presented herein, the shielding structure includes a second platform connected to the first leg and the second leg, wherein the first window is between the first platform and the second platform.

In an embodiment of the techniques presented herein, a method is provided. The method includes mounting a first component to a circuit board, mounting a shielding structure having a first platform to the circuit board, and mounting a semiconductor die to the first platform, wherein the shielding structure is between the first component and the semiconductor die.

In an embodiment of the techniques presented herein, the method includes forming a first wire bond connecting the semiconductor die and the circuit board.

In an embodiment of the techniques presented herein, the shielding structure includes a first window in the first platform, and forming the wire bond includes forming the wire bond to pass through the first window.

In an embodiment of the techniques presented herein, the method includes forming a mold compound over the circuit board, the shielding structure, and the semiconductor die.

In an embodiment of the techniques presented herein, the shielding structure includes a first leg connected to the first platform, and a first finger extending from the first leg, and the method includes removing a portion of the mold compound to expose the first finger, and forming a shield cover over the mold compound and contacting the first finger.

In an embodiment of the techniques presented herein, the shielding structure includes a first leg connected to the first platform, and a first finger extending from the first leg, and the method includes forming a trench in the mold compound exposing the first finger, forming a conductive structure in the trench connected to the first finger, and forming a shield cover over the mold compound and contacting the conductive structure.

In an embodiment of the techniques presented herein, the method includes performing a patterning process on a plate of conductive material to define the first platform, a first leg connected to the first platform, and a second leg connected to the first platform, and bending the plate of conductive material to define a first corner portion between the first leg and the first platform and to define a second corner portion between the second leg and the first platform.

Any aspect or design described herein as an “example” is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

What is claimed is:

1. An apparatus, comprising:
a circuit board;
a first component mounted to the circuit board;
a shielding structure mounted to the circuit board and having a first platform elevated over the circuit board; and
a semiconductor die mounted to the first platform,
wherein:
the shielding structure is between the first component and the semiconductor die.

2. The apparatus of claim 1, wherein the shielding structure comprises:
a first leg connected to the first platform; and
a second leg connected to the first platform.

3. The apparatus of claim 2, comprising:
a first window in the first platform; and
a wire bond connected to the circuit board and the semiconductor die, wherein:
the wire bond passes through the first window.

4. The apparatus of claim 1, comprising a mold compound over the circuit board, the shielding structure, and the semiconductor die.

5. The apparatus of claim 4, wherein:
the shielding structure comprises:
a first leg connected to the first platform; and
a first finger extending from the first leg; and
the apparatus comprises:
a shield cover over the mold compound and connected to the first finger.

6. The apparatus of claim 5, wherein:
the shielding structure comprises a second finger extending from the first leg, and
the first finger has a length greater than a length of the second finger.

7. The apparatus of claim 4, wherein:
the shielding structure comprises:
a first leg connected to the first platform; and
a first finger extending from the first leg; and
the apparatus comprises:
a shield cover over the mold compound; and
a conductive structure in the mold compound connecting the first finger and the shield cover.

8. The apparatus of claim 1, wherein:
the shielding structure is coupled to a ground plane contact of the circuit board.

9. The apparatus of claim 1, wherein:
the shielding structure comprises a second platform; and
the apparatus comprises another semiconductor die mounted to the second platform.

10. A shielding structure, comprising:
a first platform;
a first leg connected to the first platform to support the first platform;
a second leg spaced apart from the first leg and connected to the first platform to support the first platform; and
a first finger extending from the first leg, wherein:
a first window is defined in the first platform and the first finger extends into the first window.

11. The shielding structure of claim 10, comprising:
a second finger extending from the first leg and into the first window.

12. The shielding structure of claim 11, wherein the first finger has a length greater than a length of the second finger.

13. The shielding structure of claim 10, comprising:
a second platform connected to the first leg and the second leg, wherein:
the first window is between the first platform and the second platform.

14. A method, comprising:
mounting a first component to a circuit board;
mounting a shielding structure having a first platform to the circuit board; and
mounting a semiconductor die to the first platform,
wherein:
the shielding structure is between the first component and the semiconductor die.

15. The method of claim 14, comprising:
forming a wire bond connecting the semiconductor die and the circuit board.

16. The method of claim 15, wherein:
the shielding structure comprises a first window in the first platform; and
forming the wire bond comprises forming the wire bond to pass through the first window.

17. The method of claim 14, comprising:
forming a mold compound over the circuit board, the shielding structure, and the semiconductor die.

18. The method of claim 17, wherein:
the shielding structure comprises:
a first leg connected to the first platform; and
a first finger extending from the first leg; and
the method comprises:
removing a portion of the mold compound to expose the first finger; and
forming a shield cover over the mold compound and contacting the first finger.

19. The method of claim 17, wherein:
the shielding structure comprises:
a first leg connected to the first platform; and
a first finger extending from the first leg; and
the method comprises:
forming a trench in the mold compound exposing the first finger;
forming a conductive structure in the trench connected to the first finger; and
forming a shield cover over the mold compound and contacting the conductive structure.

20. The method of claim 14, comprising:
performing a patterning process on a plate of conductive material to define the first platform, a first leg connected to the first platform, and a second leg connected to the first platform; and
bending the plate of conductive material to define a first corner portion between the first leg and the first platform and to define a second corner portion between the second leg and the first platform.
